(19) United States
(12) Patent Application Publication
(10) Pub. No.: US 2025/0105127 A1
(43) Pub. Date: Mar. 27, 2025

(54) SEMICONDUCTOR PACKAGE

(71) Applicant: SAMSUNG ELECTRONICS CO., LTD., Suwon-si (KR)

(72) Inventors: Dohyun KIM, Suwon-si (KR); Yeongseon KIM, Suwon-si (KR); JUHYEON KIM, Suwon-si (KR); HYOEUN KIM, Suwon-si (KR); SUNKYOUNG SEO, Suwon-si (KR); Haksun LEE, Suwon-si (KR)

(73) Assignee: SAMSUNG ELECTRONICS CO., LTD., Suwon-si (KR)

(21) Appl. No.: 18/659,864

(22) Filed: May 9, 2024

(30) Foreign Application Priority Data
Sep. 25, 2023 (KR) 10-2023-0128344

(51) Int. Cl. H01L 23/498; H01L 23/00; H01L 23/48; H01L 23/528; H01L 23/544; H01L 25/10

(52) U.S. Cl. CPC H01L 23/49838; H01L 23/481; H01L 23/49816; H01L 23/49822; H01L 23/49866; H01L 23/5283; H01L 23/544; H01L 24/08; H01L 25/105; H01L 2223/54426; H01L 2224/08225; H01L 2225/1023; H01L 2924/1815

(57) ABSTRACT

A semiconductor package may include a first dielectric structure, a first pad in the first dielectric structure, a first semiconductor chip provided on the first dielectric structure, and a bump electrically connected to the first pad. The first semiconductor chip includes: a first substrate; a first chip dielectric layer in contact with the first dielectric structure; and a first chip pad in contact with a top surface of the first pad. The first pad may be provided between the bump and the first chip of the first semiconductor chip. The first pad may include a first conductive layer and a second conductive layer covered by the first conductive layer. The bump may be positioned closer to the first conductive layer than to the second conductive layer.

### CROSS-REFERENCE TO RELATED APPLICATION

This U.S. nonprovisional application claims priority under 35 U.S.C § 119 to Korean Patent Application No. 10-2023-0128344 filed on Sep. 25, 2023 in the Korean Intellectual Property Office, the disclosure of which is hereby incorporated by reference in its entirety.

### BACKGROUND

The present disclosure relates to a semiconductor package, and more particularly, to a semiconductor package including a semiconductor chip.

A semiconductor package is provided to implement an integrated circuit chip to qualify for use in electronic products. Typically, a semiconductor package is configured such that a semiconductor chip is mounted on a printed circuit board (PCB) and bonding wires or bumps are used to electrically connect the semiconductor chip to the printed circuit board. With the development of electronic industry, various studies have been conducted to improve reliability and durability of semiconductor packages.

### SUMMARY

One or more example embodiments of the present disclosure provide a semiconductor package with improved electrical properties and increased reliability.

According to an aspect of the disclosure, a semiconductor package may include: a first dielectric structure; a first pad in the first dielectric structure; a first semiconductor chip provided on the first dielectric structure; and a bump electrically connected to the first pad, wherein the first semiconductor chip includes: a first substrate; a first chip dielectric layer in contact with the first dielectric structure; and a first chip pad in contact with a top surface of the first pad, wherein the first pad is between the bump and the first chip pad of the first semiconductor chip, wherein the first pad comprises a first conductive layer and a second conductive layer covered by the first conductive layer, and wherein the bump is positioned closer to the first conductive layer than to the second conductive layer.

According to another aspect of the disclosure, a semiconductor package may include: a first dielectric structure; a first pad in the first dielectric structure; a first semiconductor chip provided on the first dielectric structure; and a bump electrically connected to the first pad, wherein the first semiconductor chip includes: a first substrate; a first chip dielectric layer in contact with the first dielectric structure; and a first chip pad in contact with a top surface of the first pad, wherein the first pad comprises a first conductive layer and a second conductive layer covered by the first conductive layer, wherein the first conductive layer comprises a top surface and a bottom surface that are opposite to each other, wherein the top surface of the first conductive layer is in contact with the first chip pad of the first semiconductor chip, and wherein an area at the bottom surface of the first conductive layer is greater than an area at the top surface of the first conductive layer.

According to some embodiments of the present inventive concepts, a semiconductor package may comprise: a first dielectric structure; a first pad and a plurality of key patterns in the first dielectric structure; a first semiconductor chip in contact with the first dielectric structure; a bump electrically connected to the first pad; a second dielectric structure spaced apart from the first dielectric structure across the first semiconductor chip; a first gap-fill layer between the first dielectric structure and the second dielectric structure; a second semiconductor chip in contact with the second dielectric structure; and a second gap-fill layer that surrounds the second semiconductor chip. The first pad may include a first conductive layer and a second conductive layer in the first conductive layer. The first conductive layer may include: a first part between the bump and the second conductive layer; and a second part that surrounds the second conductive layer. The first part of the first conductive layer may include a surface in contact with a bottom surface of the second conductive layer. A top surface of the second part of the first conductive layer and a top surface of the second conductive layer may be in contact with the first chip pad.

According to another aspect of the disclosure, a method of fabricating a semiconductor package may include: forming a first dielectric structure on a carrier substrate; forming a plurality of alignment keys and a first pad in the first dielectric structure at a same manufacturing step; bonding a first semiconductor chip to the first dielectric structure; removing the carrier substrate to expose the first pad and the alignment keys; and forming a bump electrically connected to the first pad.

### BRIEF DESCRIPTION OF DRAWINGS

FIG. 1A illustrates a cross-sectional view showing a semiconductor package according to some embodiments.

FIG. 1B illustrates an enlarged view showing section E1 of FIG. 1A.

FIGS. 2, 3A, 3B, 4, 5, 6, 7, 8, and 9 illustrate plan and cross-sectional views showing a method of fabricating a semiconductor package according to some embodiments.

FIG. 10 illustrates a cross-sectional view showing a semiconductor package according to some embodiments.

FIG. 11 illustrates a cross-sectional view showing a method of fabricating a semiconductor package according to some embodiments.

FIG. 12 illustrates a cross-sectional view showing a semiconductor package according to some embodiments.

FIGS. 13A and 13B illustrate plan and cross-sectional views showing a method of fabricating a semiconductor package according to some embodiments.

FIG. 14 illustrates an enlarged cross-sectional view showing a semiconductor package according to some embodiments.

FIG. 15 illustrates an enlarged cross-sectional view showing a semiconductor package according to some embodiments.

FIG. 16 illustrates a plan view showing a planar structure of a semiconductor package according to some embodiments.

FIG. 17 illustrates a plan view showing a planar structure of a semiconductor package according to some embodiments.

### DETAILED DESCRIPTION OF EMBODIMENTS

The following will describe in detail a semiconductor package and its fabrication method according to some embodiments of the present inventive concepts in conjunction with the accompanying drawings.

In the present disclosure, the term “surround” may used to describe covering, enveloping, or enclosing all sides or a portion of an object. For instance, when describing a first layer surrounded by a second layer, it may be interpreted as either all sides of the first layer being covered by the second layer, or the first layer being partially covered by the second layer, with a portion of the first layer left exposed.

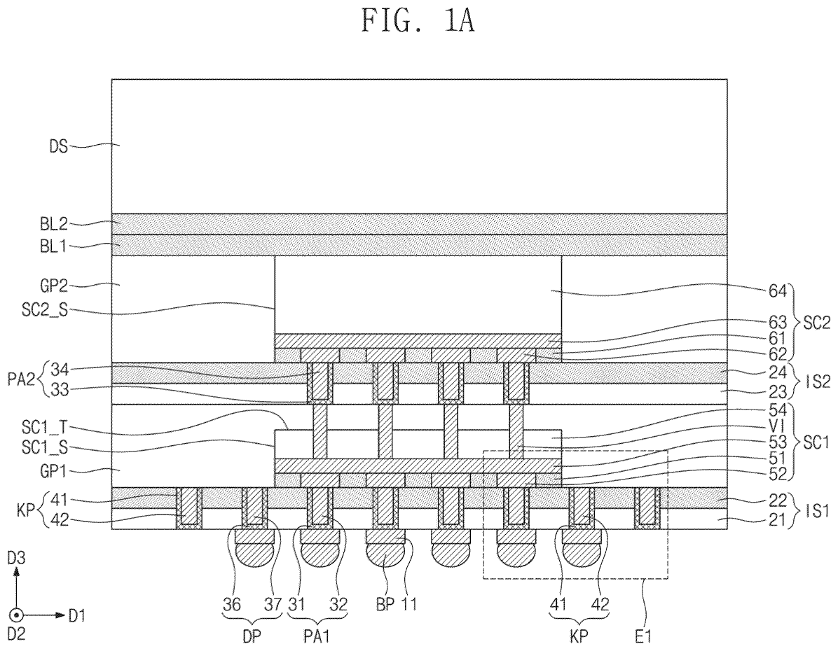

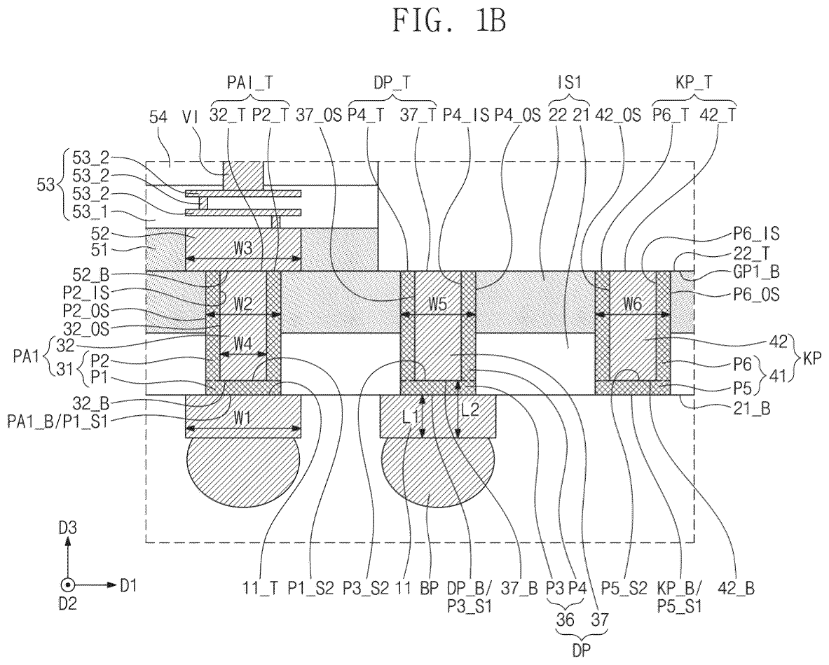

FIG. 1A illustrates a cross-sectional view showing a semiconductor package according to some embodiments. FIG. 1B illustrates an enlarged view showing section E1 of FIG. 1A.

Referring to FIGS. 1A and 1B, a semiconductor package may include bumps BP, bump connection pads 11, a first dielectric structure IS1, first pads PA1, dummy pads DP, key patterns KP, a first semiconductor chip SC1, a first gap-fill layer GP1, a second dielectric structure IS2, second pads PA2, a second semiconductor chip SC2, a second gap-fill layer GP2, a first bonding layer BL1, a second bonding layer BL2, and a dummy substrate DS. The key pattern KP may refer to specific geometric or graphical pattern on a semiconductor package that serves as a reference or alignment feature. The key pattern KP may be also referred to as an alignment mark or an alignment key. The term “pad” may be also referred to as a contact pad or a connection pad.

The first dielectric structure IS1 may include a first dielectric layer 21 and a second dielectric layer 22 on the first dielectric layer 21. Each of the first dielectric layer 21 and the second dielectric layer 22 may have a plate shape elongated along a plane defined by a first direction DI and a second direction D2. The first direction D1 and the second direction D2 may be perpendicular to each other. For example, the first direction D1 and the second direction D2 may be horizontal directions that are orthogonal to each other. The first dielectric layer 21 and the second dielectric layer 22 may include their dielectric materials different from each other. For example, the first dielectric layer 21 may include silicon oxide, and the second dielectric layer 22 may include silicon carbonitride, silicon nitride, or silicon carbon oxynitride.

A top surface 11_T of the bump connection pad 11 may be in contact with a bottom surface 21_B of the first dielectric layer 21 of the first dielectric structure IS1. The bump connection pad 11 may include a conductive material. For example, the bump connection pad 11 may include copper.

The bump BP may be in contact with a bottom surface of the bump connection pad 11. The first pad PA1 may be electrically connected through the bump connection pad 11 to the bump BP. The first pad PA1 may be disposed between the bump BP and a subsequently described first chip pad 52 of the first semiconductor chip SC1. The semiconductor package may be electrically connected through the bump BP to an external apparatus. The bump BP may include a conductive material. For example, the bump BP may include at least one selected from copper, tin, silver, and gold.

The first pads PA1, the dummy pads DP, and the key patterns KP may penetrate in a third direction D3 through the first dielectric layer 21 and the second dielectric layer 22 of the first dielectric structure IS1. The third direction D3 may be perpendicular to the first direction D1 and the second direction D2. For example, the third direction D3 may be a vertical direction perpendicular to the first direction DI and the second direction D2.

The first pads PA1, the dummy pads DP, and the key patterns KP may be placed within or surrounded by the first dielectric structure IS1. The first pads PA1, the dummy pads DP, and the key patterns KP may be disposed in the first dielectric structure IS1. A bottom surface PA1_B of the first pad PA1 may be in contact with the top surface 11_T of the bump connection pad 11. A bottom surface DP_B of the dummy pad DP may be in contact with the top surface 11_T of the bump connection pad 11. The key pattern KP may be spaced apart from the bump connection pad 11. A bottom surface KP_B of the key pattern KP may be externally exposed. The first pads PA1 and the dummy pads DP may be disposed between the key patterns KP. For example, the key patterns KP may be positioned between two opposing ends of the semiconductor package in the first direction D1, and the first pads PA1 and the dummy pads DP may be placed between the spaced-apart key patterns KP.

The first pads PA1 may be electrically connected to the first semiconductor chip SC1. The dummy pads DP and the key patterns KP may be electrically spaced apart from the first semiconductor chip SC1.

The first pad PA1 may include a first conductive layer 31 and a second conductive layer 32 surrounded by the first conductive layer 31. The second conductive layer 32 may be disposed in the first conductive layer 31. The bottom surface PA1_B of the first pad PA1 may be a bottom surface of the first conductive layer 31.

A distance in the third direction D3 between the bump BP and the bottom surface of the first conductive layer 31 may be less than a distance in the third direction D3 between the bump BP and a bottom surface 32_B of the second conductive layer 32.

The dummy pad DP may include a first dummy layer 36 and a second dummy layer 37 surrounded by the first dummy layer 36. The second dummy layer 37 may be disposed in the first dummy layer 36. The bottom surface DP_B of the dummy pad DP may be a bottom surface of the first dummy layer 36.

A distance L1 in the third direction D3 between the bump BP and the bottom surface of the first dummy layer 36 may be less than a distance L2 in the third direction D3 between the bump BP and a bottom surface 37_B of the second dummy layer 37.

The key pattern KP may include a first pattern layer 41 and a second pattern layer 42 surrounded by the first pattern layer 41. The second pattern layer 42 may be disposed in the first pattern layer 41. The bottom surface KP_B of the key pattern KP may be a bottom surface of the first pattern layer 41.

The first semiconductor chip SC1 may be provided on the first dielectric structure IS1. A bottom surface of the first semiconductor chip SC1 may be in contact with a top surface 22_T of the second dielectric layer 22 of the first dielectric structure IS1. The first semiconductor chip SC1 may be hybrid-bonded to the first dielectric structure IS1 and the first pads PA1.

The first semiconductor chip SC1 may include a first chip dielectric layer 51, first chip pads 52 in the first chip dielectric layer 51, a first wiring structure 53 on the first chip dielectric layer 51, and a first substrate 54 on the first wiring structure 53. A bottom surface of the first chip dielectric layer 51 may be in contact with the top surface 22_T of the second dielectric layer 22 of the first dielectric structure IS1. The first chip dielectric layer 51 may include a dielectric material the same as that of the second dielectric layer 22. For example, the first chip dielectric layer 51 may include silicon carbonitride, silicon nitride, or silicon carbon oxynitride.

The first chip pads 52 may be surrounded by the first chip dielectric layer 51. A bottom surface 52_B of the first chip pad 52 may be in contact with a top surface PA1_T of the first pad PA1. The dummy pad DP may be spaced apart from the first chip pad 52. The key pattern KP may be spaced apart from the first chip pad 52. The first chip pad 52 may include a conductive material. For example, the first chip pad 52 may include copper.

The first wiring structure 53 may include a first wiring dielectric layer 53_1 and first conductive structures 53_2 in the first wiring dielectric layer 53_1. The first wiring dielectric layer 53_1 of the first wiring structure 53 may be provided on the first chip dielectric layer 51. The first wiring dielectric layer 53_1 of the first wiring structure 53 may include a dielectric material. For example, the first wiring dielectric layer 53_1 of the first wiring structure 53 may include silicon oxide. In some embodiments, the first wiring dielectric layer 53_1 of the first wiring structure 53 may be a multiple layer including a plurality of dielectric layers.

The first conductive structure 53_2 of the first wiring structure 53 may include, for example, at least one selected from a conductive pad, a conductive via, and a conductive line. The first conductive structure 53_2 of the first wiring structure 53 may include a conductive material. The first conductive structure 53_2 of the first wiring structure 53 may be electrically connected to the first chip pad 52.

The first substrate 54 may be a semiconductor substrate, a dielectric substrate, a silicon-on-insulator (SOI) substrate, or a germanium-on-insulator (GOI) substrate. For example, the semiconductor substrate may include silicon, germanium, silicon-germanium, gallium-phosphorus, or gallium-arsenic.

The first semiconductor chip SC1 may further include a semiconductor device. For example, the first semiconductor chip SC1 may be a logic semiconductor chip including a logic semiconductor device or a memory semiconductor chip including a memory semiconductor device. The logic semiconductor chip may be, for example, a central processing unit (CPU), a graphic processing unit (GPU), or an application processor (AP). The memory semiconductor device may be, for example, a dynamic random access memory (DRAM) semiconductor device, a static RAM (SRAM) semiconductor device, a thyristor RAM (TRAM) semiconductor device, a zero capacitor RAM (ZRAM) semiconductor device, a twin transistor RAM (TTRAM) semiconductor device, a Flash memory semiconductor device, a magnetic RAM (MRAM) semiconductor device, a spin-transfer torque RAM (STT-MRAM) semiconductor device, a ferroelectric RAM (FRAM) semiconductor device, a phase change RAM (PRAM) semiconductor device, a polymer RAM, or an insulator resistance change memory semiconductor device.

The first gap-fill layer GP1 may be provided on the first dielectric structure IS1 and the first semiconductor chip SC1. The first gap-fill layer GP1 may surround the first semiconductor chip SC1. The first gap-fill layer GP1 may be in contact with the top surface 22_T of the second dielectric layer 22, a top surface SC1_T of the first semiconductor chip SC1, and a sidewall SC1_S of the first semiconductor chip SC1. The top surface SC1_T of the first semiconductor chip SC1 may be a top surface of the first substrate 54. The sidewall SC1_S of the first semiconductor chip SC1 may include a sidewall of the first substrate 54, a sidewall of the first wiring structure 53, and a sidewall of the first chip dielectric layer 51. The first gap-fill layer GP1 may include a dielectric material. For example, the first gap-fill layer GP1 may include silicon oxide.

A top surface DP_T of the dummy pad DP may be in contact with a bottom surface GP1_B of the first gap-fill layer GP1. A top surface KP_T of the key pattern KP may be in contact with the bottom surface GP1_B of the first gap-fill layer GP1. In some embodiments, the top surface DP_T of the dummy pad DP may be in contact with the bottom surface of the first chip dielectric layer 51.

The first semiconductor chip SC1 may further include through vias VI. The through vias VI may extend in the third direction D3. The through vias VI may penetrate the first gap-fill layer GP1 and the first substrate 54. The through via VI may be electrically connected to the first conductive structure 53_2 of the first wiring structure 53. The through via VI may include a conductive material. For example, the through via VI may include copper.

The second dielectric structure IS2 may be provided on the first gap-fill layer GP1. The second dielectric structure IS2 may include a third dielectric layer 23 and a fourth dielectric layer 24 on the third dielectric layer 23. Each of the third dielectric layer 23 and the fourth dielectric layer 24 may have a plate shape elongated along a plane defined by the first direction D1 and the second direction D2. The third dielectric layer 23 and the fourth dielectric layer 24 may include their dielectric materials different from each other. For example, the third dielectric layer 23 may include silicon oxide, and the fourth dielectric layer 24 may include silicon carbonitride, silicon nitride, or silicon carbon oxynitride.

The second dielectric structure IS2 may be spaced apart in the third direction D3 from the first dielectric structure IS1. The first semiconductor chip SC1 may be provided between the first dielectric structure IS1 and the second dielectric structure IS2. The first gap-fill layer GP1 may be provided between the first dielectric structure IS1 and the second dielectric structure IS2.

The second pads PA2 may penetrate in the third direction D3 through the third dielectric layer 23 and the fourth dielectric layer 24 of the second dielectric structure IS2. A bottom surface of the second pad PA2 may be in contact with a top surface of the through via VI and a top surface of the first gap-fill layer GP1. The second pads PA2 may be surrounded by the second dielectric structure IS2. The second pads PA2 may be provided in the second dielectric structure IS2. The second pad PA2 may be electrically connected through the through via VI to the first semiconductor chip SC1.

The second pad PA2 may include a third conductive layer 33 and a fourth conductive layer 34 surrounded by the third conductive layer 33. The fourth conductive layer 34 may be disposed in the third conductive layer 33. The bottom surface of the second pad PA2 may be a bottom surface of the third conductive layer 33.

The second semiconductor chip SC2 may be provided on the second dielectric structure IS2. A bottom surface of the second semiconductor chip SC2 may be in contact with a top surface of the fourth dielectric layer 24. The second semiconductor chip SC2 may be hybrid-bonded to the second dielectric structure IS2 and the second pads PA2.

The second semiconductor chip SC2 may include a second chip dielectric layer 61, second chip pads 62 in the second chip dielectric layer 61, a second wiring structure 63 on the second chip dielectric layer 61, and a second substrate 64 on the second wiring structure 63. A bottom surface of the second chip dielectric layer 61 may be in contact with a top surface of the fourth dielectric layer 24 of the second dielectric structure IS2. The second chip dielectric layer 61 may include a dielectric material the same as that of the fourth dielectric layer 24. For example, the second chip dielectric layer 61 may include silicon carbonitride, silicon nitride, or silicon carbon oxynitride. In some embodiments, the second chip dielectric layer 61 may be a multiple layer including a plurality of dielectric layers.

The second chip pads 62 may be surrounded by the second chip dielectric layer 61. A bottom surface of the second chip pad 62 may be in contact with a top surface of the second pad PA2. The second chip pad 62 may include a conductive material. For example, the second chip pad 62 may include copper.

The second wiring structure 63 may include a second wiring dielectric layer and second conductive structures in the second wiring dielectric layer. The second wiring dielectric layer of the second wiring structure 63 may be provided on the second chip dielectric layer 61. The second wiring dielectric layer of the second wiring structure 63 may include a dielectric material. For example, the second wiring dielectric layer of the second wiring structure 63 may include silicon oxide. In some embodiments, the second wiring dielectric layer of the second wiring structure 63 may be a multiple layer including a plurality of dielectric layers.

The second conductive structure of the second wiring structure 63 may include, for example, at least one selected from a conductive pad, a conductive via, and a conductive line. The second conductive structure of the second wiring structure 63 may include a conductive material. The second conductive structure of the second wiring structure 63 may be electrically connected to the second chip pad 62.

The second substrate 64 may be a semiconductor substrate, a dielectric substrate, a silicon-on-insulator (SOI) substrate, or a germanium-on-insulator (GOI) substrate.

The second semiconductor chip SC2 may further include a semiconductor device. For example, the second semiconductor chip SC2 may be a logic semiconductor chip including a logic semiconductor device or a memory semiconductor chip including a memory semiconductor device.

The second gap-fill layer GP2 may be provided on the second dielectric structure IS2 and the second semiconductor chip SC2. The second gap-fill layer GP2 may surround the second semiconductor chip SC2. The second gap-fill layer GP2 may be in contact with the top surface of the fourth dielectric layer 24 and a sidewall SC2_S of the second semiconductor chip SC2. The sidewall SC2_S of the second semiconductor chip SC2 may include a sidewall of the second substrate 64, a sidewall of the second wiring structure 63, and a sidewall of the second chip dielectric layer 61. The second gap-fill layer GP2 may include a dielectric material. For example, the second gap-fill layer GP2 may include silicon oxide.

The first bonding layer BL1 may be provided on the second gap-fill layer GP2 and the second substrate 64 of the second semiconductor chip SC2. The second bonding layer BL2 may be provided on the first bonding layer BL1. The first bonding layer BL1 and the second bonding layer BL2 may include the same dielectric material. For example, the first bonding layer BL1 and the second bonding layer BL2 may include silicon carbonitride, silicon nitride, or silicon carbon oxynitride.

The dummy substrate DS may be provided on the second bonding layer BL2. The dummy substrate DS may be a semiconductor substrate, a dielectric substrate, a silicon-on-insulator (SOI) substrate, or a germanium-on-insulator (GOI) substrate.

In some embodiments, the semiconductor package may not include any of the first bonding layer BL1, the second bonding layer BL2, and the dummy substrate DS. In this case, a method of fabricating the semiconductor package may include forming a glue layer on the dummy substrate DS, attaching the glue layer to the second gap-fill layer GP2 and the second semiconductor chip SC2, and removing the dummy substrate DS and the glue layer.

The first conductive layer 31 may include a first part P1 in contact with the top surface 11_T of the bump connection pad 11 and a second part P2 in contact with the bottom surface 52_B of the first chip pad 52. The second part P2 of the first conductive layer 31 may surround the second conductive layer 32. The second conductive layer 32 may be spaced apart from the bump connection pad 11. The first part P1 of the first conductive layer 31 may be interposed between the second conductive layer 32 and the bump connection pad 11. The second part P2 of the first conductive layer 31 may be provided on the first part P1 of the first conductive layer 31. The second part P2 of the first conductive layer 31 may be located at the same level as that of the second conductive layer 32. A distance in the third direction D3 between the bump connection pad 11 and the second part P2 of the first conductive layer 31 may be the same as a distance in the third direction D3 between the bump connection pad 11 and the second conductive layer 32.

The first part P1 of the first conductive layer 31 may include a first surface P1_S1 in contact with the top surface 11_T of the bump connection pad 11 and a second surface P1_S2 in contact with the bottom surface 32_B of the second conductive layer 32. The first surface P1_S1 of the first part P1 of the first conductive layer 31 may be the bottom surface PA1_B of the first pad PA1 and the bottom surface of the first conductive layer 31. The first surface P1_S1 and the second surface P1_S2 of the first part PI of the first conductive layer 31 may be parallel to each other. The first surface P1_S1 and the second surface P1_S2 of the first part Pl of the first conductive layer 31 may be parallel to the first direction D1 and the second direction D2. The first surface P1_S1 and the second surface P1_S2 of the first part P1 of the first conductive layer 31 may stand opposite to each other. An area (e.g., a planar area) at the first surface P1_S1 of the first part P1 of the first conductive layer 31 may be greater than an area (e.g., a planar area) at the second surface P1_S2 of the first part P1 of the first conductive layer 31.

The second part P2 of the first conductive layer 31 may include an outer sidewall P2_OS and an inner sidewall P2_IS. The inner sidewall P2_IS of the second part P2 of the first conductive layer 31 may be in contact with an outer sidewall 32_OS of the second conductive layer 32. The outer sidewall P2_OS of the second part P2 of the first conductive layer 31 may be in contact with the first dielectric layer 21 and the second dielectric layer 22 of the first dielectric structure IS1. The outer sidewall P2_OS and the inner sidewall P2_IS of the second part P2 of the first conductive layer 31 may be parallel to the third direction D3. The outer sidewall P2_OS and the inner sidewall P2_IS of the second part P2 of the first conductive layer 31 may stand opposite to each other.

The second part P2 of the first conductive layer 31 may include a top surface P2_T in contact with the bottom surface 52_B of the first chip pad 52. The second conductive layer 32 may include a top surface 32_T in contact with the bottom surface 52_B of the first chip pad 52. The top surface P2_T of the second part P2 of the first conductive layer 31 may be coplanar with the top surface 32_T of the second conductive layer 32. The top surface P2_T of the second part P2 of the first conductive layer 31 may be located at the same level as that of the top surface 32_T of the second conductive layer 32. The top surface P2_T of the second part P2 of the first conductive layer 31 may be a top surface of the first conductive layer 31. The top surface and the bottom surface of the first conductive layer 31 may stand opposite to each other. The top surface and the bottom surface of the first conductive layer 31 may be parallel to each other.

The area (or the planar area) at the first surface P1_S1 of the first part P1 of the first conductive layer 31 may be greater than an area (e.g., a planar area) at the top surface P2_T of the second part P2 of the first conductive layer 31. The top surface P2_T of the second part P2 of the first conductive layer 31 may have a ring shape (e.g., a tetragonal ring shape or a circular ring shape) when viewed in plan. An area (e.g., a planar area) at the top surface 32_T of the second conductive layer 32 may be greater than the area (e.g., the planar area) at the top surface P2_T of the second part P2 of the first conductive layer 31.

The first part P1 of the first conductive layer 31 may have a plate shape (e.g., a tetragonal plate shape or a circular plate shape). The second part P2 of the first conductive layer 31 may have a pipe shape (e.g., a tetragonal pipe shape or a circular pipe shape). The first part P1 of the first conductive layer 31 may be located at a level lower than that of the second part P2 of the first conductive layer 31. A distance in the third direction D3 between the first part P1 of the first conductive layer 31 and the first chip pad 52 of the first semiconductor chip SC1 may be greater than a distance in the third direction D3 between the second part P2 of the first conductive layer 31 and the first chip pad 52 of the first semiconductor chip SC1.

A width W1 in the first direction D1 of the bump connection pad 11 may be greater than a width W2 in the first direction D1 of the first pad PA1. A width W3 in the first direction D1 of the first chip pad 52 may be greater than the width W2 in the first direction D1 of the first pad PA1. The width W2 in the first direction D1 of the first pad PA1 may be a width in the first direction D1 of the first conductive layer 31. A width W4 in the first direction D1 of the second conductive layer 32 may be less than the width in the first direction D1 of the first conductive layer 31.

The first conductive layer 31 and the second conductive layer 32 may include their conductive materials different from each other. The first conductive layer 31 may include, for example, at least one selected from tantalum nitride, tantalum, titanium nitride, and titanium, but the present inventive concepts are not limited thereto. The second conductive layer 32 may include, for example, copper.

In some embodiments, the first conductive layer 31 may be a multiple layer including a first layer and a second layer. In this case, the first layer may include one of tantalum nitride, tantalum, titanium nitride, and titanium, and the second layer may include another of tantalum nitride, tantalum, titanium nitride, and titanium.

The first dummy layer 36 may include a first part P3 in contact with the top surface 11_T of the bump connection pad 11 and a second part P4 in contact with a bottom surface GP1_B of the first gap-fill layer GP1. The second part P4 of the first dummy layer 36 may surround the second dummy layer 37. The second dummy layer 37 may be spaced apart from the bump connection pad 11. The first part P3 of the first dummy layer 36 may be interposed between the second dummy layer 37 and the bump connection pad 11. The second part P4 of the first dummy layer 36 may be provided on the first part P3 of the first dummy layer 36. The second part P4 of the first dummy layer 36 may be located at the same level as that of the second dummy layer 37. A distance in the third direction D3 between the bump connection pad 11 and the second part P4 of the first dummy layer 36 may be the same as a distance in the third direction D3 between the bump connection pad 11 and the second dummy layer 37.

The first part P3 of the first dummy layer 36 may include a first surface P3_S1 in contact with the top surface 11_T of the bump connection pad 11 and a second surface P3_S2 in contact with the bottom surface 37_B of the second dummy layer 37. The first surface P3_S1 of the first part P3 of the first dummy layer 36 may be the bottom surface DP_B of the dummy pad DP. The first surface P3_S1 and the second surface P3_S2 of the first part P3 of the first dummy layer 36 may be parallel to each other. The first surface P3_S1 and the second surface P3_S2 of the first part P3 of the first dummy layer 36 may be parallel to the first direction D1 and the second direction D2. The first surface P3_S1 and the second surface P3_S2 of the first part P3 of the first dummy layer 36 may stand opposite to each other. An area (e.g., a planar area) at the first surface P3_S1 of the first part P3 of the first dummy layer 36 may be greater than an area (e.g., a planar area) at the second surface P3_S2 of the first part P3 of the first dummy layer 36.

The second part P4 of the first dummy layer 36 may include an outer sidewall P4_OS and an inner sidewall P4_IS. The inner sidewall P4_IS of the second part P4 of the first dummy layer 36 may be in contact with an outer sidewall 37_OS of the second dummy layer 37. The outer sidewall P4_OS of the second part P4 of the first dummy layer 36 may be in contact with the first dielectric layer 21 and the second dielectric layer 22 of the first dielectric structure IS1. The outer sidewall P4_OS and the inner sidewall P4_IS of the second part P4 of the first dummy layer 36 may be parallel to the third direction D3. The outer sidewall P4_OS and the inner sidewall P4_IS of the second part P4 of the first dummy layer 36 may stand opposite to each other.

The second part P4 of the first dummy layer 36 may include a top surface P4_T in contact with the bottom surface GP1_B of the first gap-fill layer GP1. The second dummy layer 37 may include a top surface 37_T in contact with the bottom surface GP1_B of the first gap-fill layer GP1. The top surface P4_T of the second part P4 of the first dummy layer 36 may be coplanar with the top surface 37_T of the second dummy layer 37. The top surface P4_T of the second part P4 of the first dummy layer 36 may be located at the same level as that of the top surface 37_T of the second dummy layer 37. The top surface P4_T of the second part P4 of the first dummy layer 36 may be a top surface of the first dummy layer 36. The area (or the planar area) at the first surface P3_S1 of the first part P3 of the first dummy layer 36 may be greater than an area (e.g., a planar area) at the top surface P4_T of the second part P4 of the first dummy layer 36. The top surface P4_T of the second part P4 of the first dummy layer 36 may have a ring shape (e.g., a tetragonal ring shape or a circular ring shape) when viewed in plan. An area (e.g., a planar area) at the top surface 37_T of the second dummy layer 37 may be greater than the area (or the planar area) at the top surface P4_T of the second part P4 of the first dummy layer 36.

The first part P3 of the first dummy layer 36 may have a plate shape (or a tetragonal plate shape or a circular plate shape). The second part P4 of the first dummy layer 36 may have a pipe shape (or a tetragonal pipe shape or a circular pipe shape). The first part P3 of the first dummy layer 36 may be located at a level lower than that of the second part P4 of the first dummy layer 36. A distance in the third direction D3 between the first part P3 of the first dummy layer 36 and the first chip pad 52 of the first semiconductor chip SC1 may be greater than a distance in the third direction D3 between the second part P4 of the first dummy layer 36 and the second chip pad 52 of the first semiconductor chip SC1.

The width W1 in the first direction D1 of the bump connection pad 11 may be greater than a width W5 in the first direction D1 of the dummy pad DP. The width W3 in the first direction D1 of the first chip pad 52 may be greater than the width W5 in the first direction D1 of the dummy pad DP.

The first dummy layer 36 and the second dummy layer 37 may include their conductive materials different from each other. The first dummy layer 36 may include at least one selected from tantalum nitride, tantalum, titanium nitride, and titanium, but the present inventive concepts are not limited thereto. The second dummy layer 37 may include, for example, copper.

In some embodiments, the first dummy layer 36 may be a multiple layer including a first layer and a second layer. In this case, the first layer may include one of tantalum nitride, tantalum, titanium nitride, and titanium, and the second layer may include another of tantalum nitride, tantalum, titanium nitride, and titanium.

The first pattern layer 41 may include a first part P5 externally exposed and a second part P6 in contact with the bottom surface GP1_B of the first gap-fill layer GP1. The second part P6 of the first pattern layer 41 may surround the second pattern layer 42. The second part P6 of the first pattern layer 41 may be provided on the first part P5 of the first pattern layer 41. The second part P6 of the first pattern layer 41 may be located at the same level as that of the second pattern layer 42. A distance in the third direction D3 between the bump connection pad 11 and the second part P6 of the first pattern layer 41 may be the same as a distance in the third direction D3 between the bump connection pad 11 and the second pattern layer 42.

The first part P5 of the first pattern layer 41 may include a first surface P5_S1 externally exposed and a second surface P5_S2 in contact with a bottom surface 42_B of the second pattern layer 42. The first surface P5_S1 of the first part P5 of the first pattern layer 41 may be the bottom surface DP_B of the key pattern KP. The first surface P5_S1 of the first part P5 of the first pattern layer 41 may be coplanar with the first surface P3_S1 of the first part P3 of the first dummy layer 36, the first surface P1_S1 of the first part P1 of the first conductive layer 31, and the bottom surface 21_B of the first dielectric layer 21. The first surface P5_S1 of the first part P5 of the first pattern layer 41 may be located at the same level as that of the first surface P3_S1 of the first part P3 of the first dummy layer 36, that of the first surface P1_S1 of the first part P1 of the first conductive layer 31, and that of the bottom surface 21_B of the first dielectric layer 21.

The first surface P5_S1 and the second surface P5_S2 of the first part P5 of the first pattern layer 41 may be parallel to each other. The first surface P5_S1 and the second surface P5_S2 of the first part P5 of the first pattern layer 41 may be parallel to the first direction D1 and the second direction D2. The first surface P5_S1 and the second surface P5_S2 of the first part P5 of the first pattern layer 41 may stand opposite to each other. An area (e.g., a planar area) at the first surface P5_S1 of the first part P5 of the first pattern layer 451 may be greater than an area (e.g., a planar area) at the second surface P5_S2 of the first part P5 of the first pattern layer 41.

The second part P6 of the first pattern layer 41 may include an outer sidewall P6_OS and an inner sidewall P6_IS. The inner sidewall P6_IS of the second part P6 of the first pattern layer 41 may be in contact with an outer sidewall 42_OS of the second pattern layer 42. The outer sidewall P6_OS of the second part P6 of the first pattern layer 41 may be in contact with the first dielectric layer 21 and the second dielectric layer 22 of the first dielectric structure IS1. The outer sidewall P6_OS and the inner sidewall P6_IS of the second part P6 of the first pattern layer 41 may be parallel to the third direction D3. The outer sidewall P6_OS and the inner sidewall P6_IS of the second part P6 of the first pattern layer 41 may stand opposite to each other.

The second part P6 of the first pattern layer 41 may include a top surface P6_T in contact with the bottom surface GP1_B of the first gap-fill layer GP1. The second dummy layer 42 may include a top surface 42_T in contact with the bottom surface GP1_B of the first gap-fill layer GP1. The top surface P6_T of the second part P6 of the first pattern layer 41 may be coplanar with the top surface 42_T of the second pattern layer 42, the top surface P4_T of the second part P4 of the first dummy layer 36, the top surface 37_T of the second dummy layer 37, the top surface P2_T of the second part P2 of the first conductive layer 31, the top surface 32_T of the second conductive layer 32, and the top surface 22_T of the second dielectric layer 22. The top surface P6_T of the second part P6 of the first pattern layer 41 may be located at the same level as that of the top surface 42_T of the second pattern layer 42, that of the top surface P4_T of the second part P4 of the first dummy layer 36, that of the top surface 37_T of the second dummy layer 37, that of the top surface P2_T of the second part P2 of the first conductive layer 31, that of the top surface 32_T of the second conductive layer 32, and that of the top surface 22_T of the second dielectric layer 22. The top surface P6_T of the second part P6 of the first pattern layer 41 may be a top surface of the first pattern layer 41. The area (or the planar area) at the first surface P5_S1 of the first part P5 of the first pattern layer 41 may be greater than an area (e.g., a planar area) at the top surface P6_T of the second part P6 of the first pattern layer 41. An area (e.g., a planar area) at the top surface 42_T of the second pattern layer 42 may be greater than the area (e.g., the planar area) at the top surface P6_T of the second part P6 of the first pattern layer 41.

The first part P5 of the first pattern layer 41 may be located at a level lower than that of the second part P6 of the first pattern layer 41. A distance in the third direction D3 between the first part P5 of the first pattern layer 41 and the first chip pad 52 of the first semiconductor chip SC1 may be greater than a distance in the third direction D3 between the second part P6 of the first pattern layer 41 and the first chip pad 52 of the first semiconductor chip SC1.

The width W1 in the first direction D1 of the bump connection pad 11 may be greater than a width W6 in the first direction D1 of the key pattern KP. The width W3 in the first direction D1 of the first chip pad 52 may be greater than the width W6 in the first direction D1 of the key pattern KP.

The first pattern layer 41 and the second pattern layer 42 may include their conductive materials different from each other. The first pattern layer 41 may include at least one selected from tantalum nitride, tantalum, titanium nitride, and titanium, but the present inventive concepts are not limited thereto. The second pattern layer 42 may include, for example, copper.

In some embodiments, the first pattern layer 41 may be a multiple layer including a first layer and a second layer. In this case, the first layer may include one of tantalum nitride, tantalum, titanium nitride, and titanium, and the second layer may include another of tantalum nitride, tantalum, titanium nitride, and titanium.

The first conductive layer 31, the first dummy layer 36, and the first pattern layer 41 may include the same conductive material. The second conductive layer 32, the second dummy layer 37, and the second pattern layer 42 may include the same conductive material.

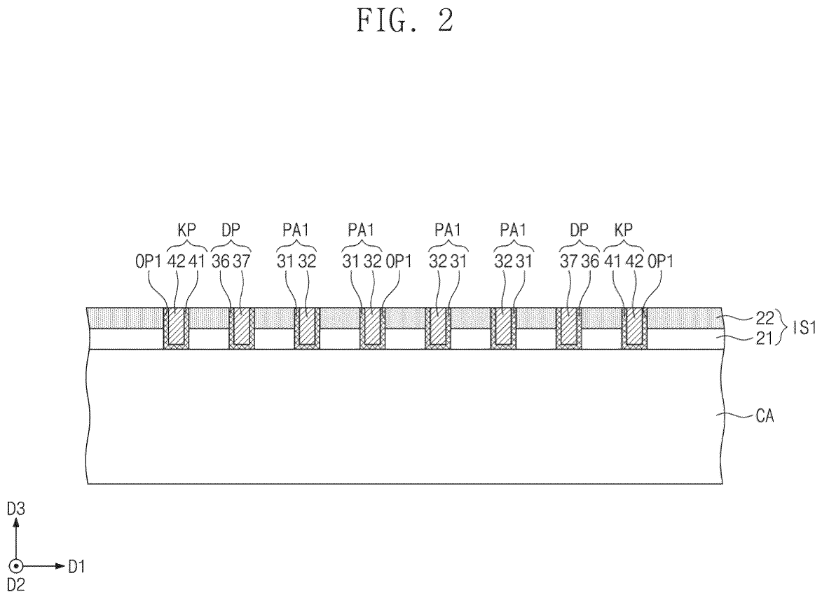

FIGS. 2, 3A, 3B, 4, 5, 6, 7, 8, and 9 illustrate plan and cross-sectional views showing a method of fabricating a semiconductor package according to some embodiments.

Referring to FIG. 2, a first dielectric structure IS1 may be formed on a carrier substrate CA. The carrier substrate CA may be, for example, a silicon substrate. The formation of the first dielectric structure IS1 may include forming a first dielectric layer 21 on the carrier substrate CA, and forming a second dielectric layer 22 on the first dielectric layer 21.

First pads PA1, dummy pads DP, and key patterns KP may be formed in the first dielectric structure IS1. The formation of the first pads PA1, the dummy pads DP, and the key patterns KP may include exposing the carrier substrate CA by forming first openings OP1 that penetrate the first dielectric structure IS1, forming a first preliminary layer on the carrier substrate CA and the first dielectric structure IS1, forming a second preliminary layer on the first preliminary layer, and removing an upper portion of the first preliminary layer and an upper portion of the second preliminary layer. In some embodiments, the second preliminary layer may be formed by an electroplating process in which the first preliminary layer is used as a seed layer. The first preliminary layer, which is used as a seed layer, becomes the first conductive layers 31, the first dummy layers 36, and the first pattern layers 41. The second preliminary layer becomes the second conductive layers 32, the second dummy layers 37, and the second pattern layers 42. According to embodiments of the present disclosure, the key patterns KP may be formed on the carrier substrate at the same time or at the same manufacturing process step as the first pads PA1 and the dummy pads DP. Consequently, the key patterns KP, the first pads PA1, and the dummy pads DP have the same structure of the seed layer, and the process of forming the first pads PA1 and the dummy pads DP may be omitted after removal of the carrier substrate. Each of the key patterns KP, the first pads PA1, and the dummy pads DP may have an inner conductive layer and an outer conductive layer that covers the inner conductive layer. The inner conductive layer may correspond to the second conductive layers 32, the second dummy layers 37, and the second pattern layers 42. The outer conductive layer may correspond to the first conductive layers 31, the first dummy layers 36, and the first pattern layers 41.

The first preliminary layer and the second preliminary layer may include their conductive materials different from each other. The first preliminary layer may include at least one selected from tantalum nitride, tantalum, titanium nitride, and titanium, but the present inventive concepts are not limited thereto. The second preliminary layer may include, for example, copper. The upper portion of the first preliminary layer may be removed such that the first preliminary layer may be separated into the first conductive layers 31, the first dummy layers 36, and the first pattern layers 41. The upper portion of the second preliminary layer may be removed such that the second preliminary layer may be separated into the second conductive layers 32, the second dummy layers 37, and the second pattern layers 42. The upper portion of the first preliminary layer may refer to a portion protruding from or extending beyond an outermost surface of the first conductive layers 31, the first dummy layers 36, and the first pattern layers 41, and may be considered a redundant portion. Similarly, the upper portion of the second preliminary layer may refer to a portion protruding from or extending beyond an outermost surface of the second conductive layers 32, the second dummy layers 37, and the second pattern layers 42, and may be considered a redundant portion.

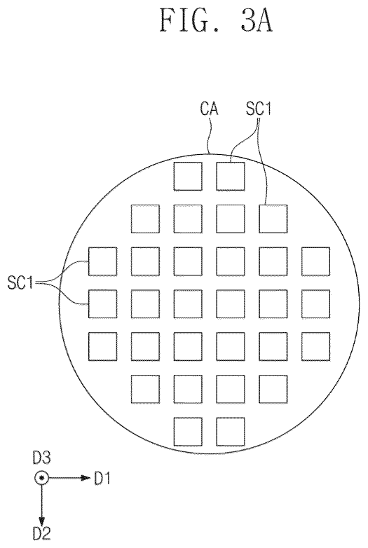

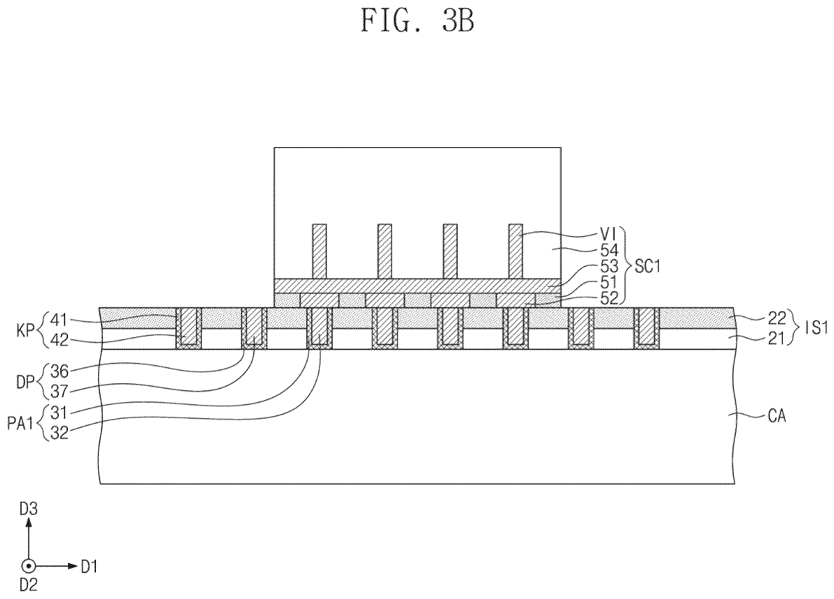

Referring to FIGS. 3A and 3B, a plurality of first semiconductor chips SC1 may be formed. The formation of the first semiconductor chip SC1 may include forming through vias VI and a first wiring structure 53 on a first substrate 54, and forming a first chip dielectric layer 51 and first chip pads 52 on the first wiring structure 53.

The plurality of first semiconductor chips SC1 may be bonded to the first dielectric structure IS1. The plurality of first semiconductor chips SC1 may be hybrid-bonded to the first dielectric structure IS1 and the first pads PA1. The first chip dielectric layer 51 of the first semiconductor chip SC1 may be bonded to the second dielectric layer 22 of the first dielectric structure IS1. The first chip pad 52 of the first semiconductor chip SC1 may be bonded to the first pad PA1.

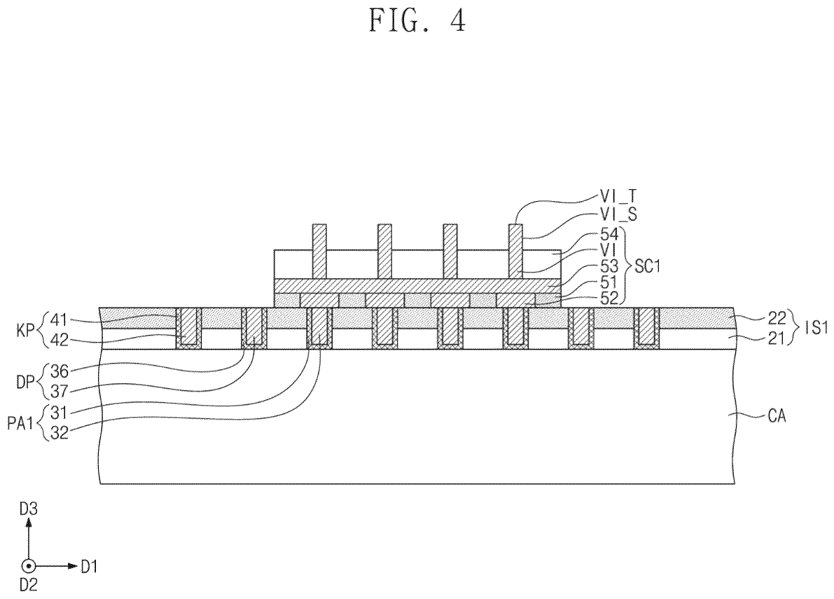

Referring to FIG. 4, an upper portion of the first substrate 54 may be removed. The upper portion of the first substrate 54 may be removed to expose a top surface VI_T of the through via VI and a portion of a sidewall VI_S of the through via VI.

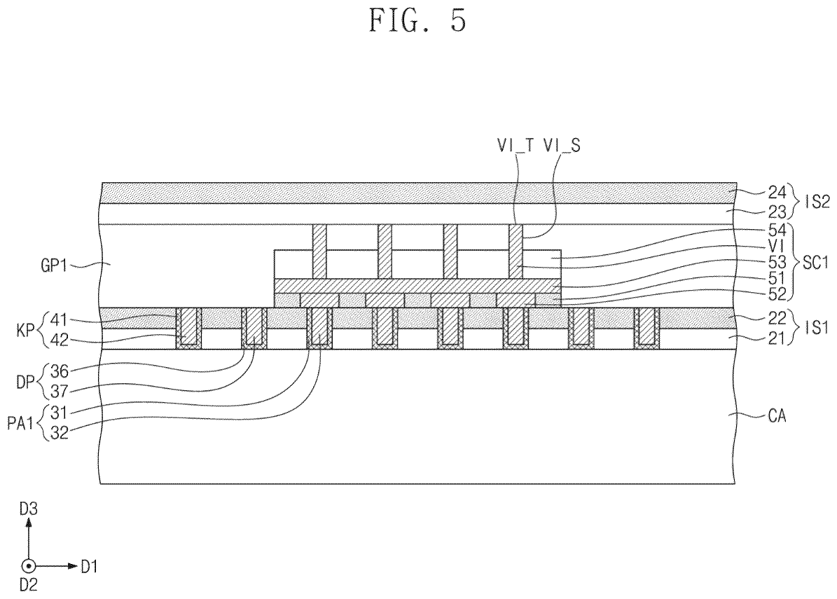

Referring to FIG. 5, a first gap-fill layer GP1 may be formed to surround the first semiconductor chip SC1. The first gap-fill layer GP1 may be in contact with a top surface of the second dielectric layer 22 of the first dielectric structure IS1, a top surface of the dummy pad DP, a top surface of the key pattern KP, a sidewall of the first semiconductor chip SC1, a top surface of the first semiconductor chip SC1, and the sidewall VI_S of the through via VI.

A second dielectric structure IS2 may be formed on the first gap-fill layer GP1. The second dielectric structure IS2 may include a third dielectric layer 23 provided on the first gap-fill layer GP1, and a fourth dielectric layer 24 provided on the third dielectric layer 23. The second dielectric structure IS2 includes second pads PA2 which are aligned to contact the through vias VI of the first dielectric structure IS1. The top surfaces VI_T of the through vias VI may be in contact with a bottom surface of the third dielectric layer 23.

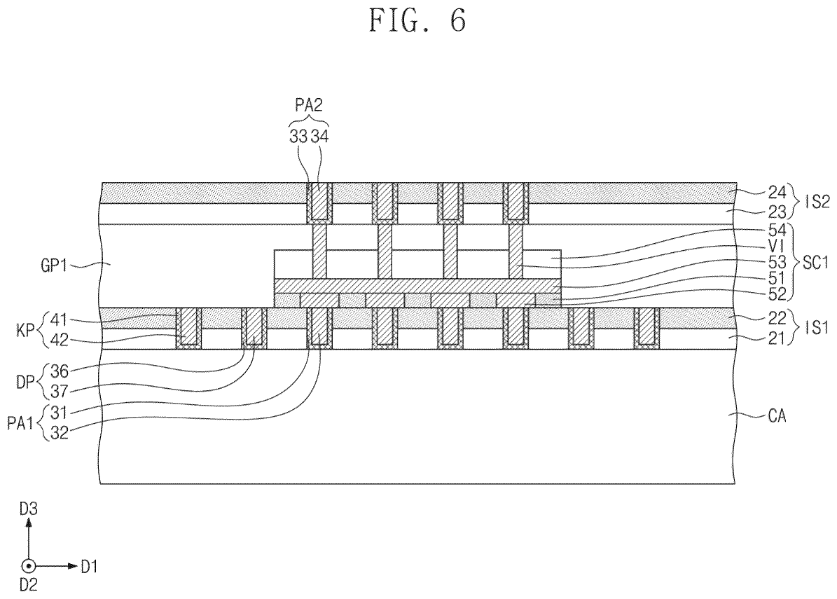

Referring to FIG. 6, the second pads PA2 may be formed in the second dielectric structure IS2. The formation of the second pads PA2 may include exposing the through vias VI and the first gap-fill layer GP1 by forming second openings OP2 that penetrate the second dielectric structure IS2, forming a third preliminary layer on the through vias VI, the first gap-fill layer GP1, and the second dielectric structure IS2, forming a fourth preliminary layer on the third preliminary layer, and removing an upper portion of the third preliminary layer and an upper portion of the fourth preliminary layer. In some embodiments, the fourth preliminary layer may be formed by an electroplating process in which the third preliminary layer is used as a seed.

Conductive materials included in the third preliminary layer and the fourth preliminary layer may be different from each other. For example, the third preliminary layer may include at least one selected from tantalum nitride, tantalum, titanium nitride, and titanium, while embodiments of the present disclosure are not limited thereto. The fourth preliminary layer may include, for example, copper. The upper portion of the third preliminary layer may be removed such that the third preliminary layer may be separated into third conductive layers 33. The upper portion of the fourth preliminary layer may be removed such that the fourth preliminary layer may be separated into fourth conductive layers 34.

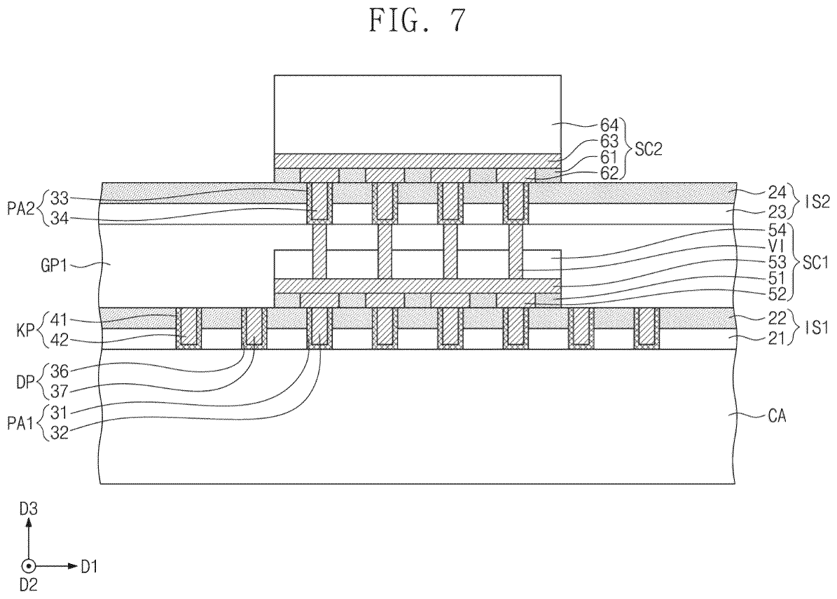

Referring to FIG. 7, a plurality of second semiconductor chips SC2 may be formed. The formation of the second semiconductor chip SC2 may include forming a second wiring structure 63 on a second substrate 64, and forming a second chip dielectric layer 61 and second chip pads 62 on the second wiring structure 63.

The plurality of second semiconductor chips SC2 may be bonded to the second dielectric structure IS2. The plurality of second semiconductor chips SC2 may be hybrid-bonded to the second dielectric structure IS2 and the second pads PA2. The second chip dielectric layer 61 of the second semiconductor chip SC2 may be bonded to the fourth dielectric layer 24 of the second dielectric structure IS2. The second chip pad 62 of the second semiconductor chip SC2 may be bonded to the second pad PA2.

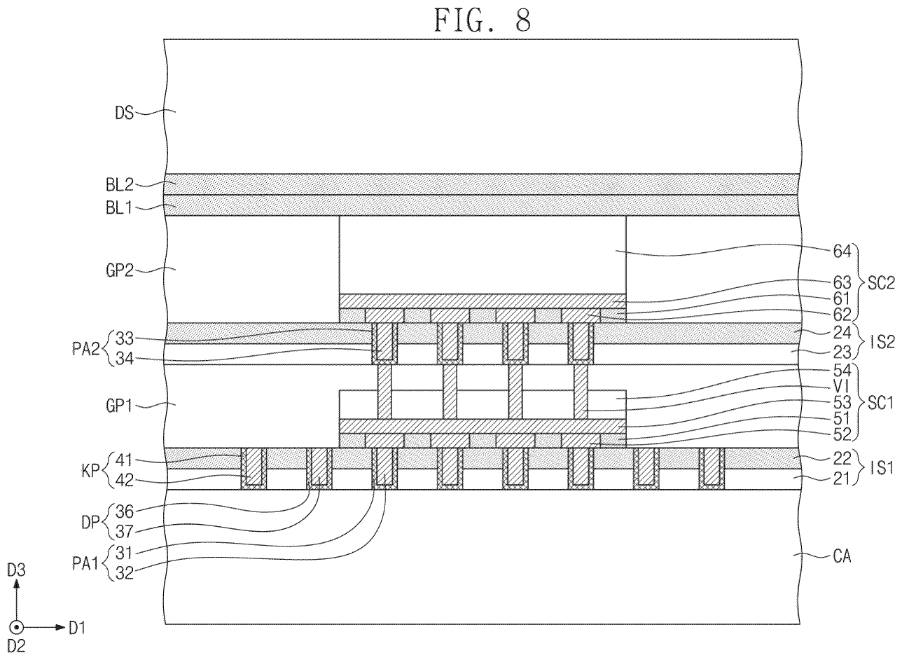

Referring to FIG. 8, a second gap-fill layer GP2 may be formed to surround the second semiconductor chip SC2. The second gap-fill layer GP2 may be in contact with a top surface of the fourth dielectric layer 24 and a sidewall of the second semiconductor chip SC2.

A first bonding layer BL1 may be formed on the second gap-fill layer GP2. A second bonding layer BL2 may be formed on a dummy substrate DS. A wafer bonding process may be employed to bond the first bonding layer BL1 and the second bonding layer BL2 to each other.

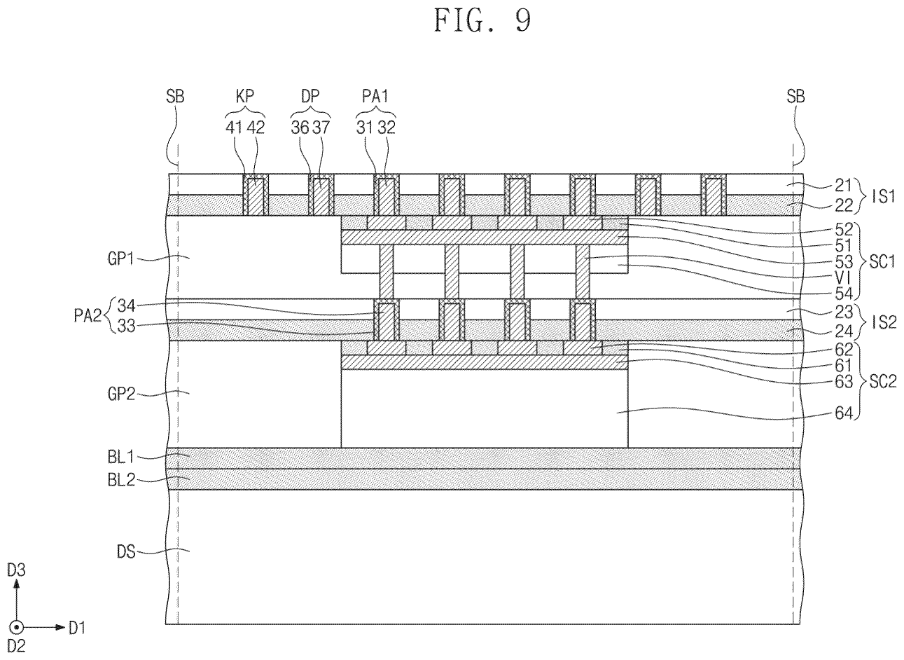

Referring to FIG. 9, the carrier substrate CA and the dummy substrate DS may be turned upside down. Afterwards, the carrier substrate CA may be removed. In some embodiments, the carrier substrate CA may be removed by a grinding process. The carrier substrate CA may be removed to expose the first pads PA1, the dummy pads DP, and the key patterns KP.

A scribing line SB may be defined which will be discussed below. Neighboring scribing lines SB may be provided therebetween with the key patterns KP, the dummy pads DP, the first pads PA1, the first semiconductor chip SC1, the second pads PA2, and the second semiconductor chip SC2.

Referring to FIG. 1A, bump connection pads 11 and bumps BP may be formed. The key patterns KP may serve as an alignment key in a process for forming the bump connection pads 11 and the bumps BP. In some embodiments, the key patterns KP may serve as an alignment key in a process other than the process for forming the bump connection pads 11 and the bumps BP.

A scribing process may be performed along the scribing lines SB. The scribing process may cut the first dielectric layer 21 and the second dielectric layer 22 of the first dielectric structure IS1, the first gap-fill layer GP1, the third dielectric layer 23 and the fourth dielectric layer 24 of the second dielectric structure IS2, the second gap-fill layer GP2, the first bonding layer BL1, the second bonding layer BL2, and the dummy substrate DS.

The first dielectric layer 21 may be cut and separated into a plurality of first dielectric layers 21. The second dielectric layer 22 may be cut and separated into a plurality of second dielectric layers 22. The third dielectric layer 23 may be cut and separated into a plurality of third dielectric layers 23. The fourth dielectric layer 24 may be cut and separated into a plurality of fourth dielectric layers 24. The first gap-fill layer GP1 may be cut and separated into a plurality of first gap-fill layers GP1. The second gap-fill layer GP2 may be cut and separated into a plurality of second gap-fill layers GP2. The first bonding layer BL1 may be cut and separated into a plurality of first bonding layers BL1. The second bonding layer BL2 may be cut and separated into a plurality of second bonding layers BL2. The dummy substrate DS may be cut and separated into a plurality of dummy substrates DS.

In a method of fabricating a semiconductor package according to some embodiments, as the key patterns KP and the first pads PA1 are formed simultaneously with each other, it may be possible to omit a process for forming a pad in the first dielectric structure IS1 after the carrier substrate CA is removed, which may result in a simplification of the fabrication of the semiconductor packages.

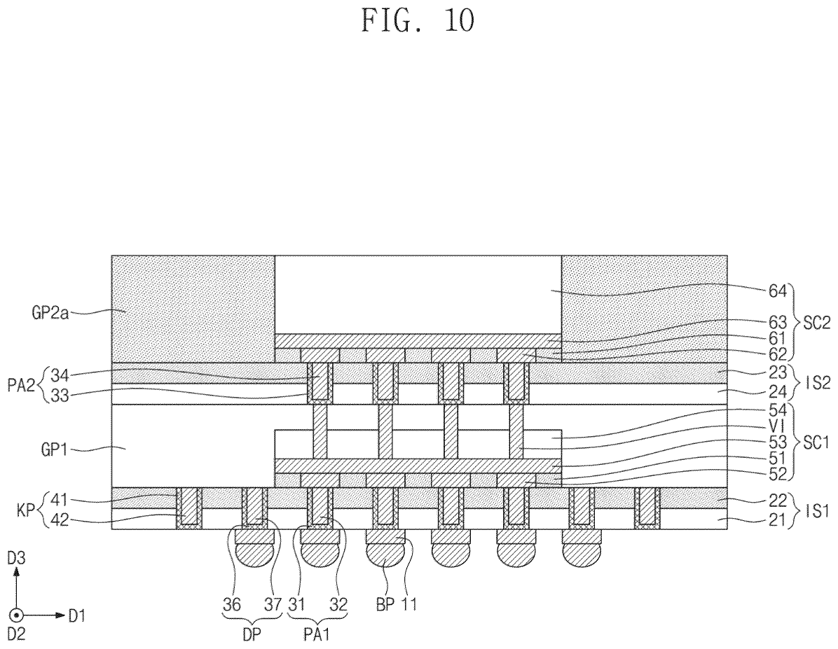

FIG. 10 illustrates a cross-sectional view showing a semiconductor package according to some embodiments. A semiconductor package of FIG. 10 may be the same or substantially the same as the semiconductor package of FIGS. 1A and 1B, except for the description below.

Referring to FIG. 10, a second gap-fill layer GP2a may include a polymeric material. For example, the second gap-fill layer GP2a may include an epoxy resin.

None of a first bonding layer, a second bonding layer, and a dummy wafer may be provided on the second semiconductor chip SC2 and the second gap-fill layer GP2a. The second semiconductor chip SC2 and the second gap-fill layer GP2a may have externally exposed top surfaces.

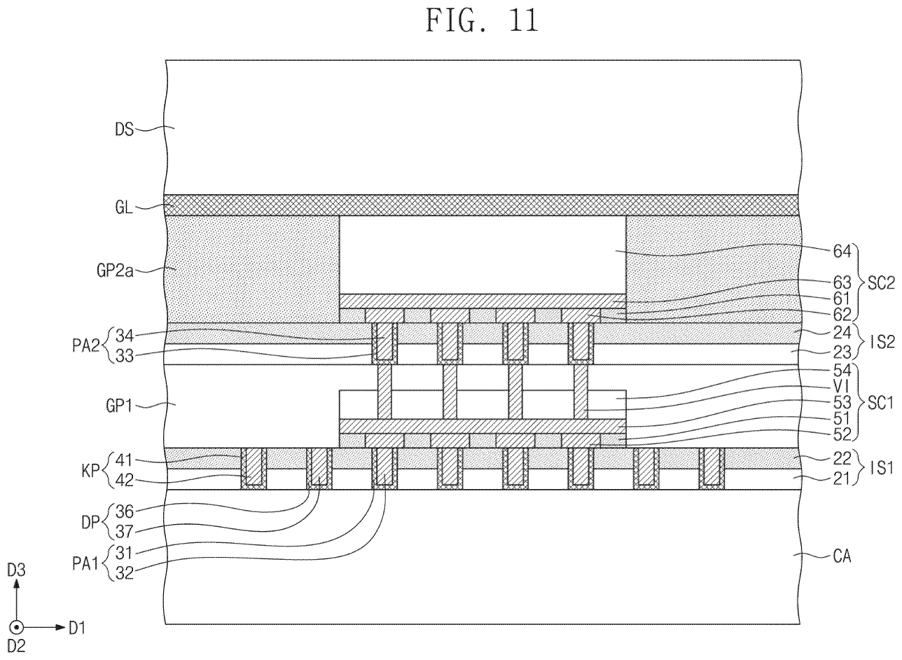

FIG. 11 illustrates a cross-sectional view showing a method of fabricating a semiconductor package according to some embodiments.

Referring to FIG. 11, similarly to that discussed in FIGS. 2 to 7, a semiconductor package may include a carrier substrate CA, a first dielectric structure IS1, first pads PA1, dummy pads DP, key patterns KP, first semiconductor chips SC1, a first gap-fill layer GP1, a second dielectric structure IS2, second pads PA2, second semiconductor chips SC2, and a second gap-fill layer GP2a.

A glue layer GL may be formed on a dummy substrate DS. The glue layer GL may include an adhesive polymeric material. The glue layer GL may be attached to the second semiconductor chip SC2 and the second gap-fill layer GP2a.

Referring to FIG. 10, the dummy substrate DS and the carrier substrate CA may be turned upside down. After the carrier substrate CA is removed, bump connection pads 11 and bumps BP may be formed. A scribing process may be performed. The glue layer GL and the dummy substrate DS may be removed.

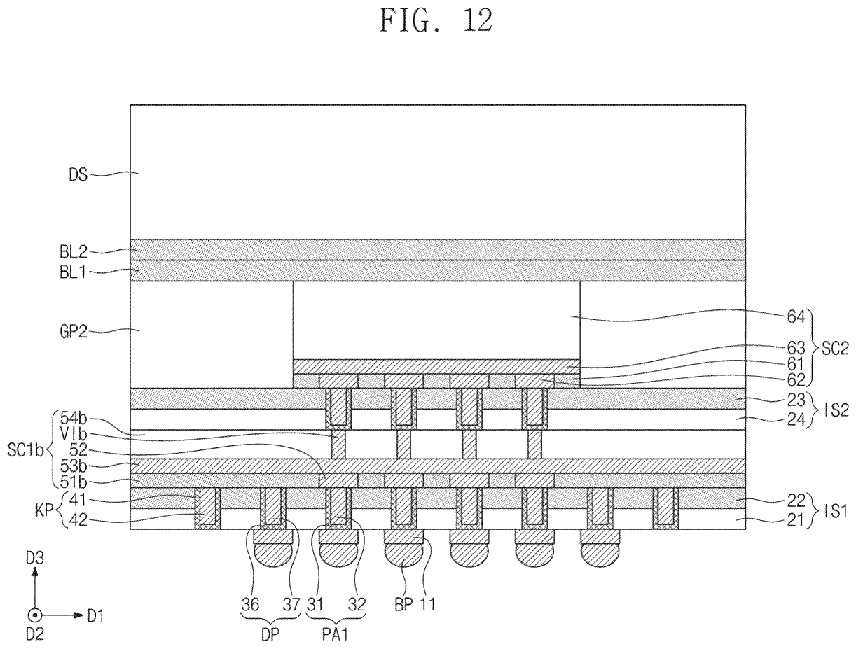

FIG. 12 illustrates a cross-sectional view showing a semiconductor package according to some embodiments. A semiconductor package of FIG. 12 may be the same or substantially the same as the semiconductor package of FIGS. 1A and 1B, except for the description below.

Referring to FIG. 12, a first semiconductor chip SC1b may have the same width as that of the first dielectric structure IS1, that of the second dielectric structure IS2, that of the first bonding layer BL1, that of the second bonding layer BL2, and that of the dummy substrate DS. For example, the first semiconductor chip SC1b may have the same width in the first direction D1 as that of the first dielectric structure IS1, that of the second dielectric structure IS2, that of the first bonding layer BL1, that of the second bonding layer BL2, and that of the dummy substrate DS. The first semiconductor chip SC1b may have a sidewall coplanar with that of the first dielectric structure IS1, that of the second dielectric structure IS2, that of the first bonding layer BL1, that of the second bonding layer BL2, and that of the dummy substrate DS.

The first semiconductor chip SC1b may include a first chip dielectric layer 51b, first chip pads 52, a first wiring structure 53b, through vias VIb, and a first substrate 54b. The first chip dielectric layer 51b, the first wiring structure 53b, and the first substrate 54b may have the same width as that of the first dielectric structure IS1, that of the second dielectric structure IS2, that of the first bonding layer BL1, that of the second bonding layer BL2, and that of the dummy substrate DS. For example, the first chip dielectric layer 51b, the first wiring structure 53b, and the first substrate 54b may have the same width in the first direction D1 as that of the first dielectric structure IS1, that of the second dielectric structure IS2, that of the first bonding layer BL1, that of the second bonding layer BL2, and that of the dummy substrate DS. The first chip dielectric layer 51b, the first wiring structure 53b, and the first substrate 54b may have their sidewalls coplanar with that of the first dielectric structure IS1, that of the second dielectric structure IS2, that of the first bonding layer BL1, that of the second bonding layer BL2, and that of the dummy substrate DS.

The dummy pads DP and the key patterns KP may have their top surfaces in contact with a bottom surfaced of the first chip dielectric layer 51b. The first substrate 54b may have a top surface in contact with a bottom surface of the third dielectric layer 23. The through via VIb may have a top surface coplanar with that of the first substrate 54b. The top surface of the through via VIb may be located at the same level as that of the top surface of the first substrate 54b.

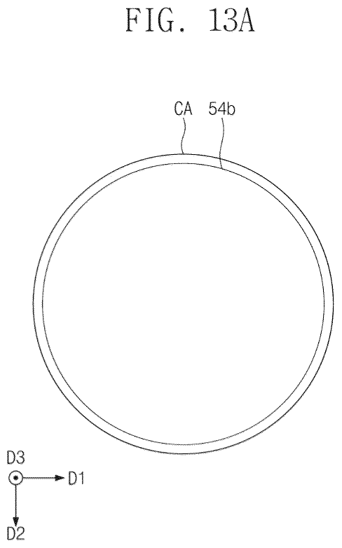

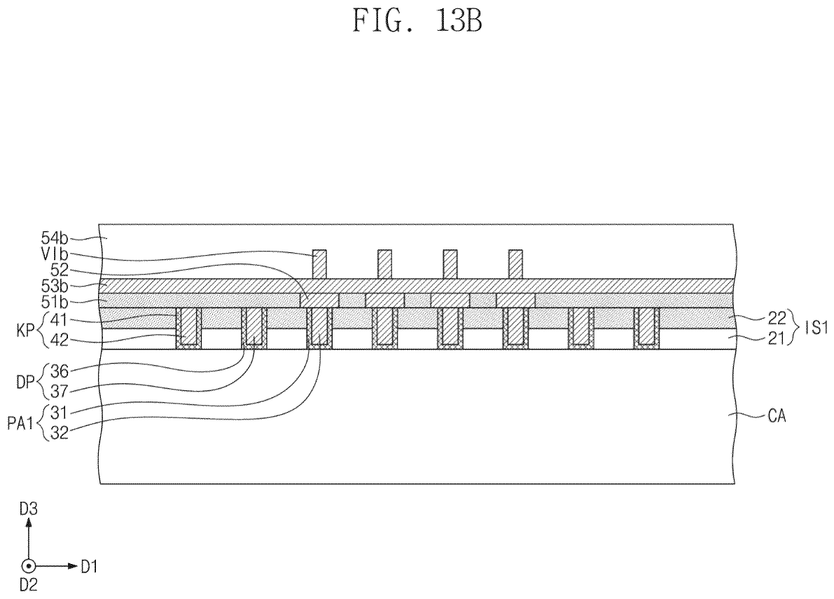

FIGS. 13A and 13B illustrate plan and cross-sectional views showing a method of fabricating a semiconductor package according to some embodiments.

Referring to FIGS. 13A and 13B, similarly to that discussed in FIG. 2, there may be formed a carrier substrate CA, a first dielectric structure IS1, first pads PA1, dummy pads DP, and key patterns KP.

Through vias VIb may be formed on a first substrate 54b. A first wiring structure 53b may be formed on the first substrate 54b. A first chip dielectric layer 51b may be formed on the first wiring structure 53b. First chip pads 52 may be formed in the first chip dielectric layer 51b.

The first chip dielectric layer 51b and the first chip pads 52 may be bonded to the first pads PA1 and a second dielectric layer 22 of the first dielectric structure IS1. The first chip dielectric layer 51b and the first chip pads 52 may be hybrid-bonded to the first pads PA1 and the second dielectric layer 22 of the first dielectric structure IS1.

Referring to FIG. 12, an upper portion of the first substrate 54b may be removed. Similarly to that discussed in FIGS. 4 to 9, the semiconductor package may include a second dielectric structure IS2, second pads PA2, a second semiconductor chip SC2, a second gap-fill layer GP2, a first bonding layer BL1, a second bonding layer BL2, and a dummy substrate DS.

After the carrier substrate CA is removed, bump connection pads 11 and bumps BP may be formed. A scribing process may be performed. The scribing process may cut the first chip dielectric layer 51b, the first wiring structure 53b, and the first substrate 54b.

The first chip dielectric layer 51b may be cut and separated into a plurality of first chip dielectric layers 51b. The first wiring structure 53b may be cut and separated into a plurality of first wiring structures 53b. The first substrate 54b may be cut and separated into a plurality of first substrates 54b. A first semiconductor chip SC1b may include the separated first chip dielectric layer 51b, the separated first wiring structure 53b, and the separated first substrate 54b.

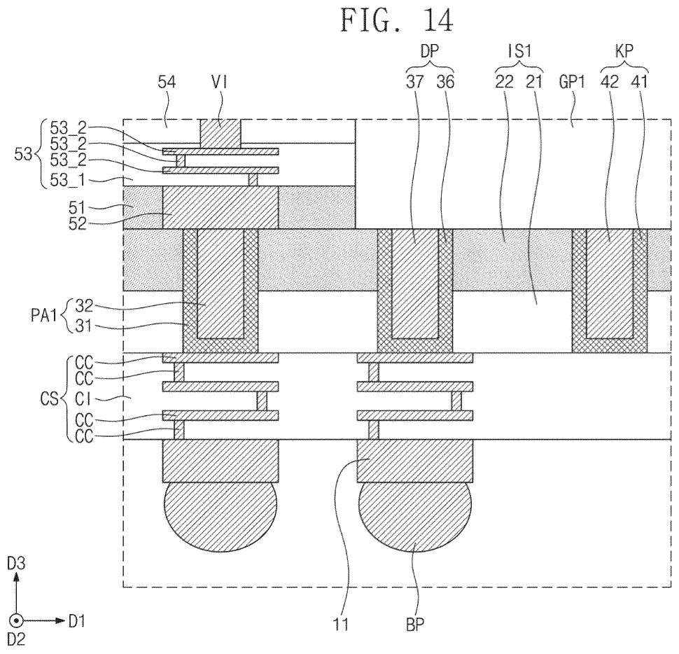

FIG. 14 illustrates an enlarged cross-sectional view showing a semiconductor package according to some embodiments. A semiconductor package of FIG. 14 may be similar to the semiconductor package of FIGS. 1A and 1B, except for the description below.

Referring to FIG. 14, a semiconductor package may further include a connection structure CS between the first dielectric structure IS1 and the bump connection pads 11. The connection structure CS may be provided between the bump BP and the first dielectric structure IS1. A width in the first direction D1 of the connection structure CS may be the same as a width in the first direction D1 of the first dielectric structure IS1. A width in the second direction D2 of the connection structure CS may be the same as a width in the second direction D2 of the first dielectric structure IS1.

The connection structure CS may include a connection dielectric layer CI and connection conductive structures CC. A top surface of the connection dielectric layer CI may be in contact with a bottom surface of the first dielectric structure IS1. A bottom surface of the key pattern KP may be in contact with the top surface of the connection dielectric layer CI. A bottom surface of the connection dielectric layer CI may be in contact with a top surface of the bump connection pad 11. In some embodiments, differently from that shown, at least one of the bump connection pad 11 may be provided in the connection dielectric layer CI. The connection dielectric layer CI may include a dielectric material. For example, the connection dielectric layer CI may include silicon oxide. In some embodiments, the connection dielectric layer CI may be a multiple layer including a plurality of dielectric layers.

The connection conductive structures CC may be provided in the connection dielectric layer CI. The connection conductive structures CC may be surrounded by the connection dielectric layer CI. One of the connection conductive structures CC may electrically connect the bump connection pad 11 to the first pad PA1. Another of the connection conductive structures CC may electrically connect the bump connection pad 11 to the dummy pad DP. The connection conductive structures CC may include, for example, at least one of a conductive pad, a conductive via, and a conductive line.

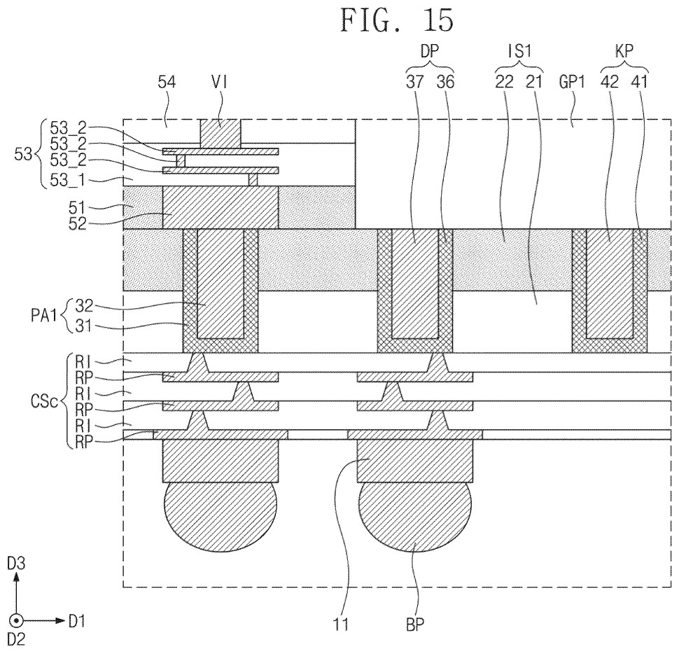

FIG. 15 illustrates an enlarged cross-sectional view showing a semiconductor package according to some embodiments. A semiconductor package of FIG. 15 may be the same or substantially the same as the semiconductor package of FIGS. 1A and 1B, except for the description below.

Referring to FIG. 15, a semiconductor package may further include a connection structure CSc between the first dielectric structure IS1 and the bump connection pads 11. The connection structure CSc may be a redistribution substrate including redistribution dielectric layers RI and redistribution patterns RP.

The redistribution dielectric layers RI may be stacked along the third direction D3. The redistribution dielectric layers RI may include a photo-imageable dielectric material. The photo-imageable dielectric material may include, for example, at least one selected from photosensitive polyimide, polybenzoxazole, phenolic polymers, and benzocyclobutene polymers.

The redistribution patterns RP may be provided in the redistribution dielectric layers RI. The redistribution patterns RP may be surrounded by the redistribution dielectric layers RI. One of the redistribution patterns RP may electrically connect the bump connection pad 11 to the first pad PA1. Another of the redistribution patterns RP may electrically connect the bump connection pad 11 to the dummy pad DP. The redistribution patterns RP may include a conductive material. The redistribution pattern RP may include a via part that extends in a vertical direction and a line part that extends in a horizontal direction.

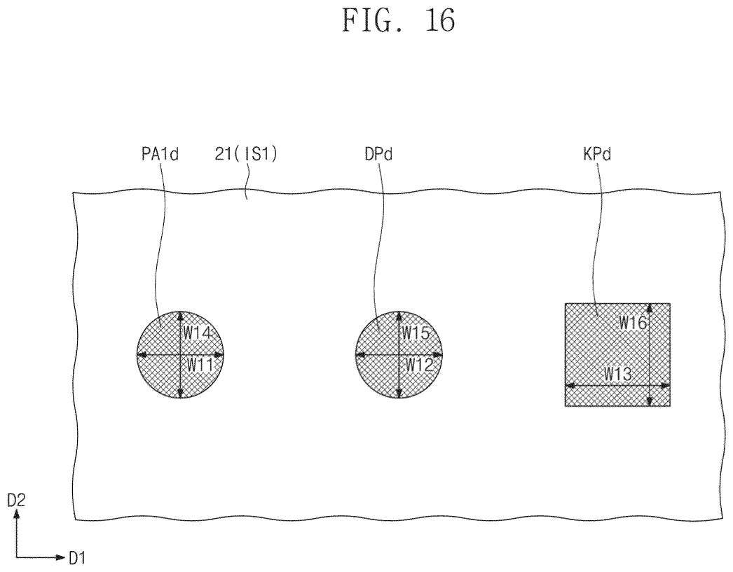

FIG. 16 illustrates a plan view showing a planar structure of a semiconductor package according to some embodiments. A semiconductor package of FIG. 16 may be similar to the semiconductor package of FIGS. 1A and 1B, except for the description below.

Referring to FIG. 16, a first pad PA1d and a dummy pad DPd may each have a circular shape when viewed in plan. A first surface of a first part included in a first conductive layer of the first pad PA1d may have a circular shape when viewed in plan, and likewise a first surface of a first part included in a first dummy layer of the dummy pad DPd may have a circular shape when viewed in plan. When viewed in plan, a key pattern KPd may have a shape different from that of the first pad PA1d and that of the dummy pad DPd. The key pattern KPd may have a tetragonal shape when viewed in plan. A first surface of a first part included in a first pattern layer of the key pattern KPd may have a tetragonal shape when viewed in plan.

In some embodiments, the first pad PA1d and the dummy pad DPd may each have an oval shape or a polygonal shape when viewed in plan.

The first pad PA1d and the dummy pad DPd may have their planar sizes less than that of the key pattern KPd. For example, a maximum width W11 in the first direction D1 of the first pad PA1d and a maximum width W12 in the first direction D1 of the dummy pad DPd may be less than a maximum width W13 in the first direction D1 of the key pattern KPd, and a maximum width W14 in the second direction D2 of the first pad PA1d and a maximum width W15 in the second direction D2 of the dummy pad DPd may be less than a maximum width W16 in the second direction D2 of the key pattern KPd.

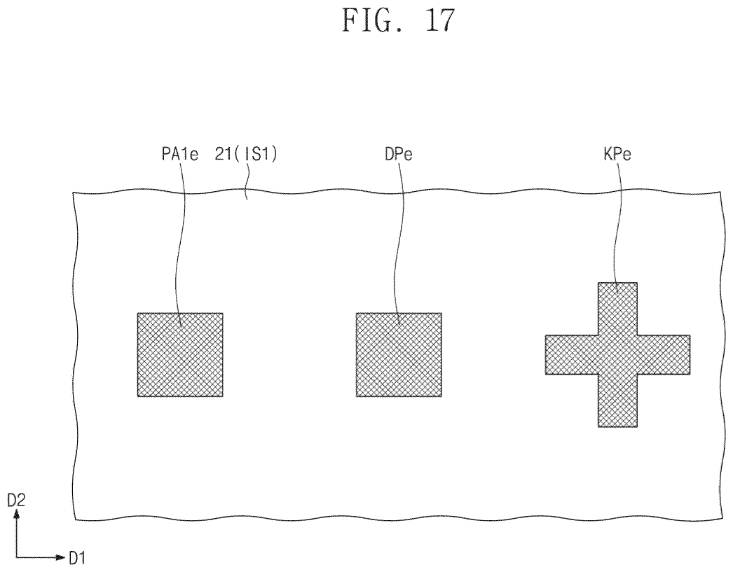

FIG. 17 illustrates a plan view showing a planar structure of a semiconductor package according to some embodiments. A semiconductor package of FIG. 17 may be the same or substantially the same as the semiconductor package of FIGS. 1A and 1B, except for the description below.

Referring to FIG. 17, a first pad PA1e and a dummy pad DPe may each have a tetragonal shape when viewed in plan. When viewed in plan, a key pattern KPe may have a shape different from that of the first pad PA1e and that of the dummy pad DPe. The key pattern KPe may have a cross shape when viewed in plan.

In a semiconductor package according to some embodiments of the present inventive concepts, key patterns and a pad bonded to a semiconductor chip may be formed simultaneously to simplify a fabrication process of the semiconductor package.

Although embodiments of the present disclosure has been described in connection with the some embodiments of the present inventive concepts illustrated in the accompanying drawings, it will be understood by one of ordinary skill in the art that variations in form and detail may be made therein without departing from the spirit and essential feature of the present inventive concepts. The above disclosed embodiments should thus be considered illustrative and not restrictive.

1. A semiconductor package comprising:
a first dielectric structure;
a first pad in the first dielectric structure;
a first semiconductor chip provided on the first dielectric structure; and
a bump electrically connected to the first pad,
wherein the first semiconductor chip includes:
a first substrate;
a first chip dielectric layer in contact with the first dielectric structure; and
a first chip pad in contact with a top surface of the first pad,
wherein the first pad is provided between the bump and the first chip pad of the first semiconductor chip,
wherein the first pad comprises a first conductive layer and a second conductive layer covered by the first conductive layer, and
wherein the bump is positioned closer to the first conductive layer than to the second conductive layer.

2. The semiconductor package of claim 1, wherein conductive materials of the first conductive layer and conductive materials of the second conductive layer are different.

3. The semiconductor package of claim 1, wherein the first conductive layer comprises:
a first part in contact with the bottom surface of the second conductive layer; and
a second part in contact with the first chip pad of the first semiconductor chip,
wherein the second part covers the second conductive layer.

4. The semiconductor package of claim 3, wherein the first part of the first conductive layer is between the bump and the second conductive layer.

5. The semiconductor package of claim 3, wherein an inner sidewall of the second part of the first conductive layer is in contact with an outer sidewall of the second conductive layer.

6. The semiconductor package of claim 1, wherein the first dielectric structure comprises a first dielectric layer and a second dielectric layer on the first dielectric layer,
wherein the second dielectric layer is in contact with the first chip dielectric layer of the first semiconductor chip, and
wherein the first dielectric layer and the second dielectric layer comprise different dielectric materials from each other.

7. The semiconductor package of claim 6, wherein
the first dielectric layer comprises silicon oxide, and
the second dielectric layer comprises silicon nitride, silicon carbonitride, or silicon carbon oxynitride.

8. The semiconductor package of claim 7, wherein a dielectric material included in the first chip dielectric layer is identical to the dielectric material of the second dielectric layer.

9. The semiconductor package of claim 1, further comprising:
a second dielectric structure spaced apart from the first dielectric structure across the first semiconductor chip;
a second pad in the second dielectric structure; and
a gap-fill layer between the first dielectric structure and the second dielectric structure,
wherein the first semiconductor chip comprises a through via that electrically connects the second pad and the first semiconductor chip to each other.

10. The semiconductor package of claim 9, further comprising a second semiconductor chip in contact with the second dielectric structure,
wherein the second semiconductor chip comprises:
a second substrate;
a second chip dielectric layer in contact with the second dielectric structure; and
a second chip pad in contact with the second pad.

11. A semiconductor package comprising:
a first dielectric structure;
a first pad in the first dielectric structure;
a first semiconductor chip provided on the first dielectric structure; and
a bump electrically connected to the first pad,
wherein the first semiconductor chip includes:
a first substrate;
a first chip dielectric layer in contact with the first dielectric structure; and
a first chip pad in contact with a top surface of the first pad,
wherein the first pad comprises a first conductive layer and a second conductive layer covered by the first conductive layer,
wherein the first conductive layer comprises a top surface and a bottom surface that are opposite to each other,
wherein the top surface of the first conductive layer is in contact with the first chip pad of the first semiconductor chip, and
wherein an area at the bottom surface of the first conductive layer is greater than an area at the top surface of the first conductive layer.

12. The semiconductor package of claim 11, wherein the top surface of the first conductive layer has a ring shape when viewed in plan.

13. The semiconductor package of claim 11, wherein
the first conductive layer comprises at least one selected from tantalum nitride, tantalum, titanium nitride, and titanium, and
the second conductive layer comprises copper.

14. The semiconductor package of claim 11, wherein the second conductive layer comprises a top surface in contact with the first chip pad,
wherein an area at the top surface of the second conductive layer is greater than the area at the top surface of the first conductive layer.

15. The semiconductor package of claim 11, wherein a width of the first chip pad is greater than a width of the first pad.

16. The semiconductor package of claim 11, further comprising a plurality of alignment keys in the first dielectric structure,
wherein the first pad is between the alignment keys.

17. The semiconductor package of claim 16, wherein the alignment keys comprise a first pattern layer and a second pattern layer covered by the first pattern layer,
wherein the first pattern layer comprises:
a first part in contact with a bottom surface of the second pattern layer; and
a second part in contact with an outer sidewall of the second pattern layer.

18. The semiconductor package of claim 16, further comprising a gap-fill layer that covers the first semiconductor chip,
wherein the alignment keys are in contact with the gap-fill layer.

19. A semiconductor package, comprising:
a first dielectric structure;
a first pad and a plurality of key patterns in the first dielectric structure;
a first semiconductor chip in contact with the first dielectric structure;
a bump electrically connected to the first pad;
a second dielectric structure spaced apart from the first dielectric structure across the first semiconductor chip;
a first gap-fill layer between the first dielectric structure and the second dielectric structure;
a second semiconductor chip in contact with the second dielectric structure; and
a second gap-fill layer that surrounds the second semiconductor chip,
wherein the first pad includes a first conductive layer and a second conductive layer in the first conductive layer,
wherein the first conductive layer includes:
a first part between the bump and the second conductive layer; and
a second part that surrounds the second conductive layer,
wherein the first part of the first conductive layer includes a surface in contact with a bottom surface of the second conductive layer, and
wherein a top surface of the second part of the first conductive layer and a top surface of the second conductive layer are in contact with the first chip pad.

20. The semiconductor package of claim 19, wherein top surfaces of the key patterns are in contact with a bottom surface of the first gap-fill layer.

21.-28. (canceled)
